(19) United States
(12) Patent Application Publication
(10) Pub. No.: US 2025/0280737 A1
(43) Pub. Date: Sep. 4, 2025

(54) MEMORY DEVICE AND METHOD FOR FORMING THE SAME

(71) Applicants: TAIWAN SEMICONDUCTOR MANUFACTURING COMPANY, LTD., Hsinchu (TW); NATIONAL TAIWAN UNIVERSITY, Taipei (TW)

(72) Inventors: Jiun-Yun LI, Taipei City (TW); Yu-Cheng LI, Taoyuan City (TW); Che-Hao CHANG, Hsinchu City (TW); Yu-Jui WU, Taipei City (TW)

(73) Assignees: TAIWAN SEMICONDUCTOR MANUFACTURING COMPANY, LTD., Hsinchu (TW); NATIONAL TAIWAN UNIVERSITY, Taipei (TW)

(21) Appl. No.: 18/595,038

(22) Filed: Mar. 4, 2024

(51) Int. Cl. H10N 60/10; G06N 10/40; H10N 60/01

(52) U.S. Cl. CPC H10N 60/128; G06N 10/40; H10N 60/01; H10N 60/11

(57) ABSTRACT

A memory device includes a substrate. A gate dielectric layer is over the substrate. A first plunger gate structure and a second plunger gate structure are over the gate dielectric layer, wherein in a top view the first and second plunger gate structures are arranged concentrically, and wherein each of the first and second plunger gate structures comprises a ring structure and plunger gates extend downwardly from the ring structure. Barrier gates are over the gate dielectric layer, wherein in a cross-sectional view each of the plunger gates of the first and second plunger gate structures is laterally between adjacent two of the barrier gates.

### BACKGROUND

The semiconductor integrated circuit (IC) industry has experienced rapid growth. Technological advances in IC materials and design have produced generations of ICs. Each generation has smaller and more complex circuits than the previous generation. However, these advances have increased the complexity of processing and manufacturing ICs. In the course of IC evolution, functional density (i.e., the number of interconnected devices per chip area) has generally increased while geometric size (i.e., the smallest component (or line) that can be created using a fabrication process) has decreased. This scaling-down process generally provides benefits by increasing production efficiency and lowering associated costs. However, since feature sizes continue to decrease, fabrication processes continue to become more difficult to perform. Therefore, it is a challenge to form reliable semiconductor devices at smaller and smaller sizes.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A to 9C illustrate a method for manufacturing a memory device at various stages in accordance with some embodiments of the present disclosure.

FIG. 10A is a top view of a memory device in accordance with some embodiments of the present disclosure.

FIG. 10B is a cross-sectional view of a memory device in accordance with some embodiments of the present disclosure.

FIG. 11 shows simulation results in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. As used herein, “around,” “about,” “approximately,” or “substantially” may generally mean within 20 percent, or within 10 percent, or within 5 percent of a given value or range. Numerical quantities given herein are approximate, meaning that the term “around,” “about,” “approximately,” or “substantially” can be inferred if not expressly stated. One skilled in the art will realize, however, that the values or ranges recited throughout the description are merely examples, and may be reduced or varied with the down-scaling of the integrated circuits.

Quantum computing is capable of solving intractable problems by classical computers, owing to the entanglement and superposition properties of qubits (quantum bits). Si-based spin qubits are promising due to their long decoherence in enriched ²⁸Si quantum dots (QDs) and compatibility with Si very large-scale integration (VLSI) technology. For practical applications, the number of qubits (or QDs) needs to be as large as possible. Thus, the architecture of QDs is critical for large-scale qubits. 1D linear QD arrays are commonly used for large-scale qubits. In the present disclosure, a novel 2D architecture of QD arrays with a larger density is provided, enabling qubit a large-scale spin qubit system compatible with VLSI technologies.

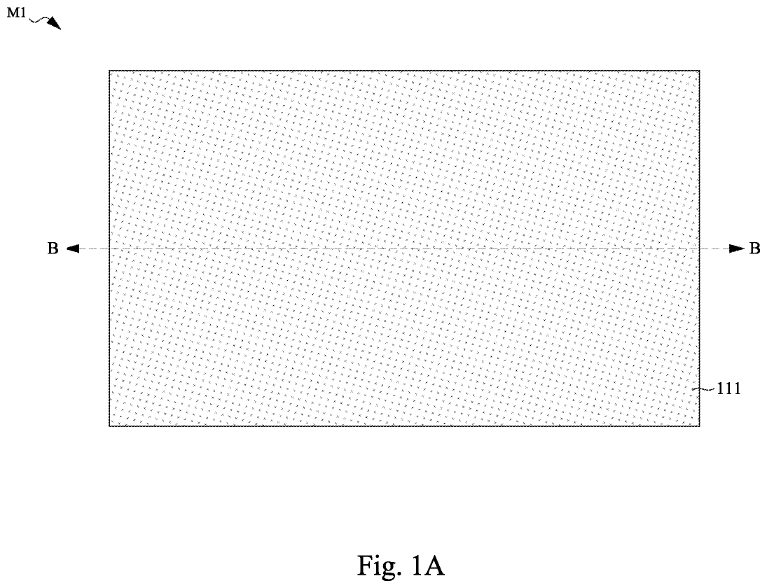

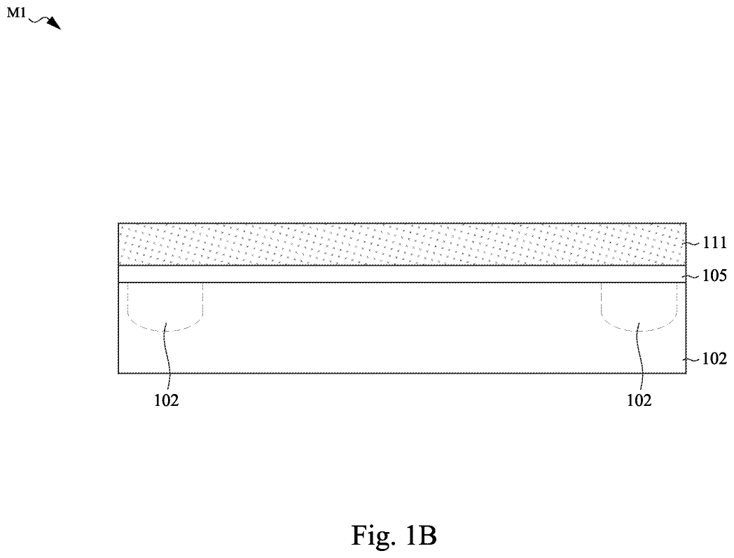

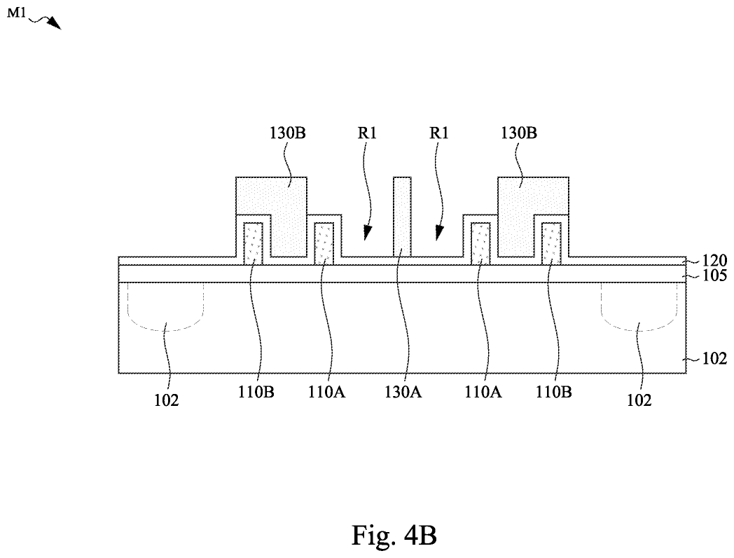

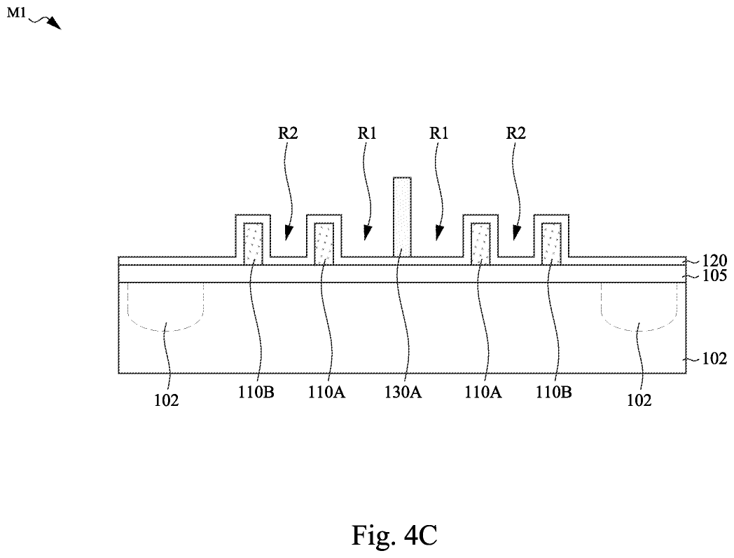

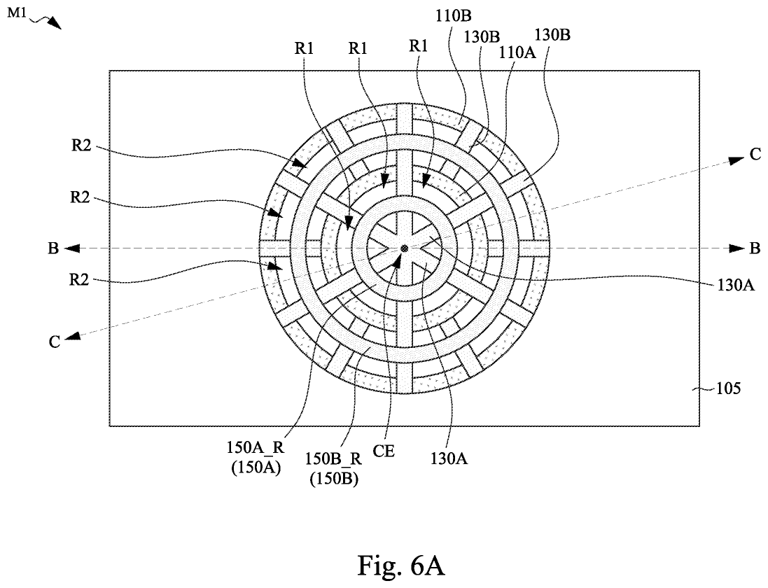

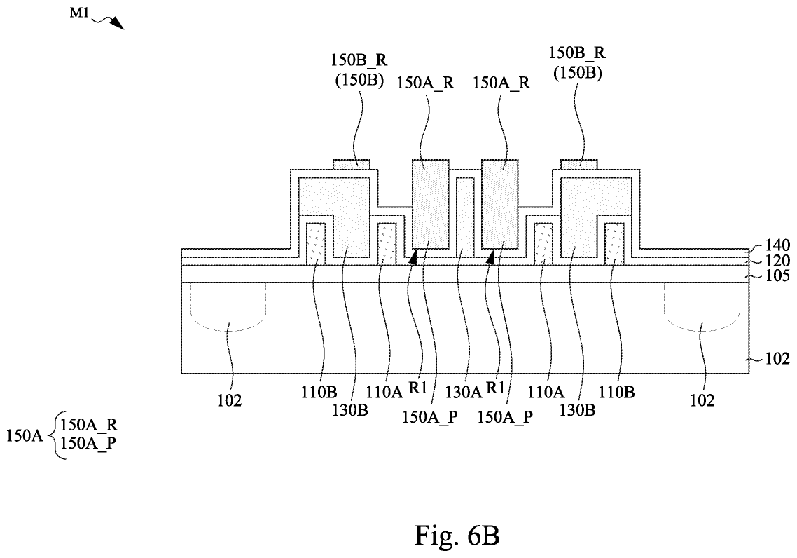

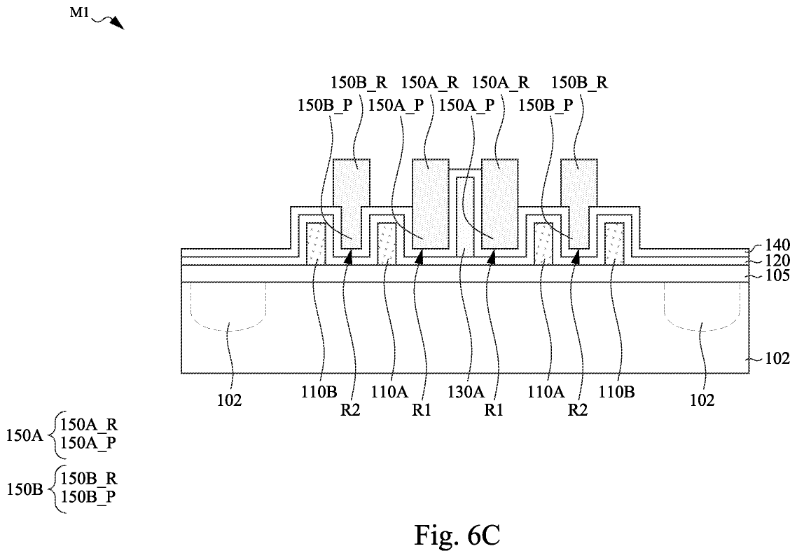

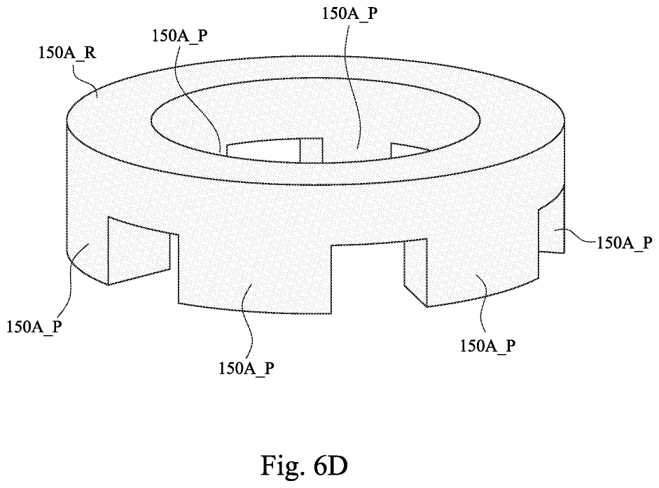

FIGS. 1A to 9C illustrate a method for manufacturing a memory device at various stages in accordance with some embodiments of the present disclosure. In greater detail, FIGS. 1A, 2A, 3A, 4A, 5A, 6A, 7A, 8A, and 9A are top views of a memory device. FIGS. 1B, 2B, 3B, 4B, 5B, 6B, 7B, 8B, and 9B are cross-sectional views along line B-B of FIGS. 1A, 2A, 3A, 4A, 5A, 6A, 7A, 8A, and 9A, respectively. FIGS. 4C, 5C, 6C, 7C, 8C, and 9C are cross-sectional views along line C-C of FIGS. 4A, 5A, 6A, 7A, 8A, and 9A, respectively. It is noted that some elements in the cross-sectional views are omitted in the top views for simplicity. FIG. 6D is a schematic view of a plunger gate structure of FIG. 6A. It is noted that some elements in the cross-sectional views are omitted in the top views for simplicity.

Although the views shown in FIGS. 1A to 9C are described with reference to a method, it will be appreciated that the structures shown in FIGS. 1A to 9C are not limited to the method but rather may stand alone separate of the method. Although FIGS. 1A to 9C are described as a series of acts, it will be appreciated that these acts are not limiting in that the order of the acts can be altered in other embodiments, and the methods disclosed are also applicable to other structures. In other embodiments, some acts that are illustrated and/or described may be omitted in whole or in part.

Reference is made to FIGS. 1A and 1B. Shown there is a memory device M1. The memory device M1 includes a substrate 100. The substrate 100 may be a semiconductor substrate, such as a bulk semiconductor, a semiconductor-on-insulator (SOI) substrate, or the like. The substrate 100 may be a wafer, such as a silicon wafer. Generally, an SOI substrate includes a layer of a semiconductor material formed on an insulator layer. The insulator layer may be, for example, a buried oxide (BOX) layer, a silicon oxide layer, or the like. The insulator layer is provided on a substrate, a silicon or glass substrate. Other substrates, such as a multi-layered or gradient substrate may also be used. In some embodiments, the semiconductor material of the substrate 100 may include silicon; germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof.

Source/drain regions 102 are formed in the substrate 100. The source/drain regions 102 may be doped regions in the substrate 100, and may be formed using suitable process, such as an implantation process. The doping species may include p-type dopants, such as boron or BF₂; n-type dopants, such as phosphorus or arsenic; and/or other suitable dopants including combinations thereof. In some embodiments where electrons are used as carriers, the source/drain regions 102 may be n-type doped regions, and the substrate 100 may be p-type substrate. On the other hand, when holes are used as carriers, the source/drain regions 102 may be p-type doped regions, and the substrate 100 may be n-type substrate.

A gate dielectric layer 105 is formed over the substrate 100. In some embodiments, the gate dielectric layer 105 may include oxide, such as aluminum oxide (Al₂O₃), silicon oxide (SiO₂), or the like. The gate dielectric layer 105 may also include high-k dielectric material, such as HfO₂, HfSiO, HfSiON, HfTaO, HfTiO, HfZrO, zirconium oxide, aluminum oxide, titanium oxide, hafnium dioxide-alumina (HfO₂—Al₂O₃) alloy, other suitable high-k dielectric materials, and/or combinations thereof. The gate dielectric layer 105 may be formed using suitable deposition process, such as atomic layer deposition (ALD), chemical vapor deposition (CVD), physical vapor deposition (PVD), or other suitable deposition processes.

A gate layer 111 is formed over the gate dielectric layer 105. In some embodiments, the gate layer 111 may be made of conductive material, such as metal, and can also be referred to as a metal layer. In some embodiments, the gate layer 111 may include tungsten (W), aluminum (Al), copper (Cu), gold (Au), chromium (Cr), or the like. In other embodiments, the gate layer 111 may include titanium (Ti), titanium nitride (TiN), or the like. The gate layer 111 may be formed using suitable deposition process, such as sputtering, chemical vapor deposition (CVD), physical vapor deposition (PVD), atomic layer deposition (ALD), or other suitable deposition processes.

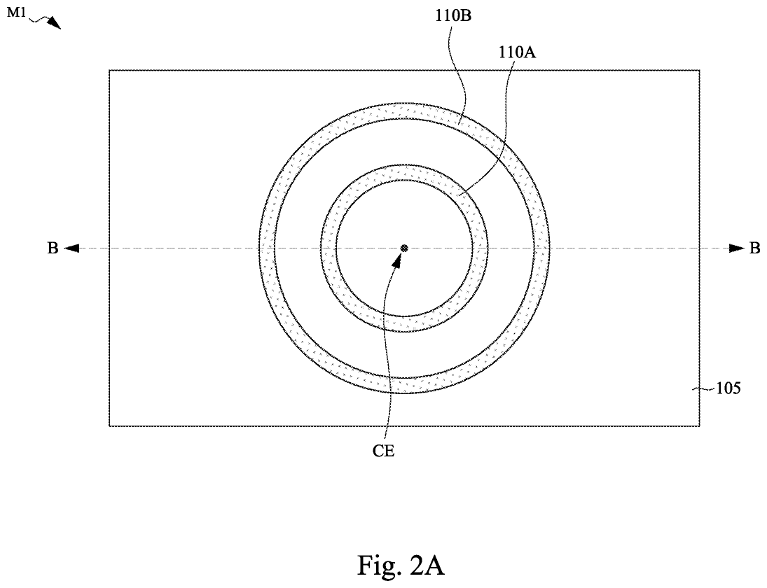

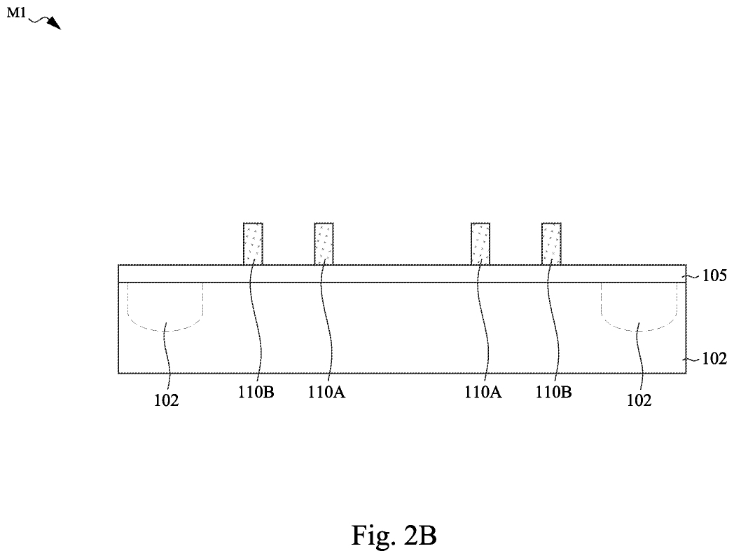

Reference is made to FIGS. 2A and 2B. The gate layer 111 is patterned to form a barrier gate 110A and a barrier gate 110B separated from each other. As shown in the top view of FIG. 2A, each of the barrier gates 110A and 110B includes an annular top profile (or a circular-ring shape top profile). In some embodiments, the barrier gates 110A and 110B are arranged concentrically with respect to a center CE, in which the barrier gate 110B surrounds the barrier gate 110A. In some embodiments, the barrier gates 110A and 110B may also be referred to as annular barrier gates.

In some embodiments, the gate layer 111 may be patterned using suitable photolithography process. For example, a patterned mask (e.g., photoresist) layer is formed over the gate layer 111, the patterned mask may include openings that define the profiles of the barrier gates 110A and 110B, an etching process is performed to remove portions of the gate layer 111 through the openings of the patterned mask, and the patterned mask is then removed once the etching process is complete. In some embodiments, the etching process may be reactive ion etching (RIE) process, or may be other suitable etching process.

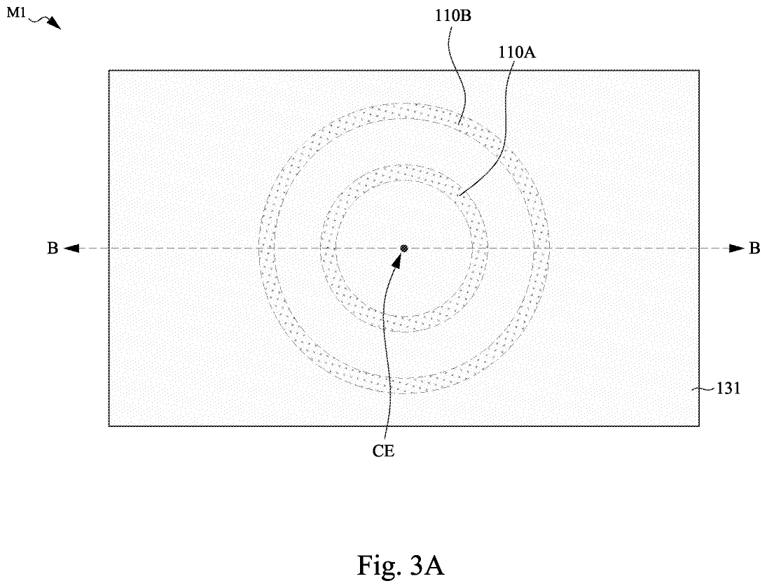

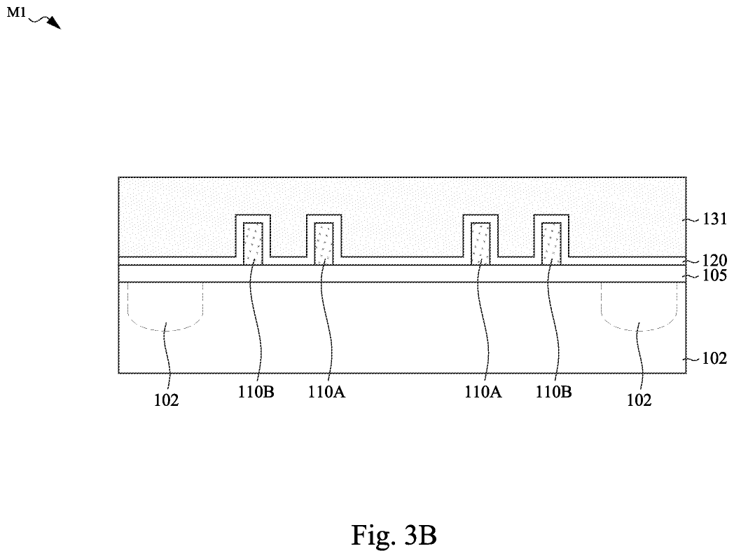

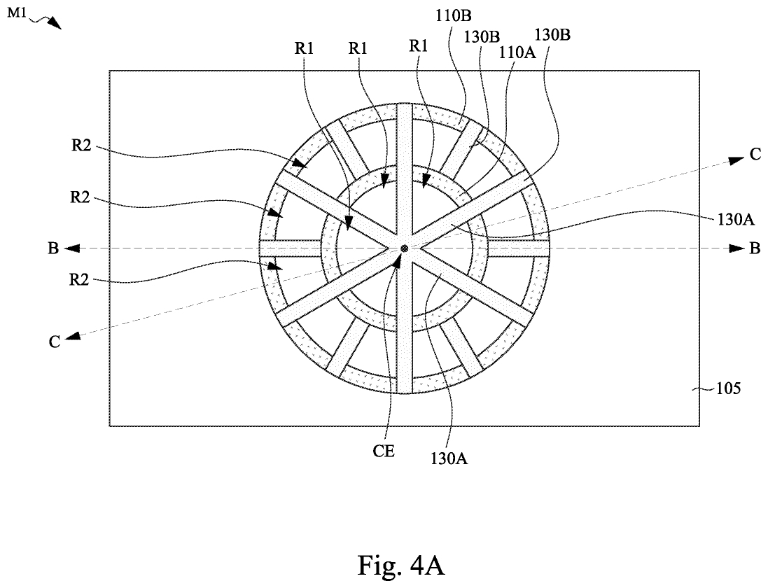

Reference is made to FIGS. 3A and 3B. A gate dielectric layer 120 is formed over the substrate 100 and lining the underlying structure. In greater detail, the gate dielectric layer 120 is deposited in a conformal manner, such that the gate dielectric layer 120 lines the top surface of the gate dielectric layer 105, and lines the top surface and opposite sidewalls of each of the barrier gates 110A and 110B. In some embodiments, the gate dielectric layer 120 may include oxide, such as aluminum oxide (Al₂O₃), silicon oxide (SiO₂), or the like. The gate dielectric layer 120 may also include high-k dielectric material, such as HfO₂, HfSiO, HfSiON, HfTaO, HfTiO, HfZrO, zirconium oxide, aluminum oxide, titanium oxide, hafnium dioxide-alumina (HfO₂—Al₂O₃) alloy, other suitable high-k dielectric materials, and/or combinations thereof. The gate dielectric layer 120 may be formed using suitable deposition process, such as atomic layer deposition (ALD), chemical vapor deposition (CVD), physical vapor deposition (PVD), or other suitable deposition processes.

A gate layer 131 is formed over the gate dielectric layer 120. In greater detail, the gate layer 131 may cover the barrier gates 110A and 110B, and may fill the spaces adjacent to the barrier gates 110A and 110B. For example, the gate layer 131 fills the circular region within the barrier gate 110A, the ring shape region between the barrier gates 110A and 110B, and the region outside the barrier gate 110B. In some embodiments, the gate layer 131 is deposited such that the top surface of the gate layer 131 is higher than the top surfaces of the barrier gates 110A and 110B. In some embodiments, the top surfaces of the barrier gates 110A and 110B is lower than the top surface of the gate layer 131 and is higher than the bottom surfaces of the gate layer 131.

In some embodiments, the gate layer 131 may be made of conductive material, such as metal, and can also be referred to as a metal layer. In some embodiments, the gate layer 131 may include tungsten (W), aluminum (Al), copper (Cu), gold (Au), chromium (Cr), or the like. In other embodiments, the gate layer 131 may include titanium (Ti), titanium nitride (TiN), or the like. The gate layer 131 may be formed using suitable deposition process, such as sputtering, chemical vapor deposition (CVD), physical vapor deposition (PVD), atomic layer deposition (ALD), or other suitable deposition processes.

Reference is made to FIGS. 4A, 4B, and 4C. The gate layer 131 is patterned to form barrier gates 130A and 130B. Here, the barrier gates 130A may be referred to as the portions of the patterned gate layer 131 extend from the center CE to the barrier gate 110A. The barrier gates 130B may be referred to as the portions of the patterned gate layer 131 extend from the barrier gate 110A to the barrier gate 110B. In some embodiments, the barrier gates 130A are connected with each other at the center CE. As shown in the top view of FIG. 4A, each of the barrier gates 130A and 130B includes a linear top profile (or a bar-shape top profile). In some embodiments, each of the barrier gates 130A and 130B are arranged radially with respect to the center CE. Accordingly, the barrier gates 130A and 130B can also be referred to as radial gates or linear gates.

In some embodiments, parts of the barrier gates 130B are connected with the barrier gates 130A, while parts of the barrier gates 130B are free of connection with the barrier gates 130A. As an example of FIG. 4A, if one barrier gate 130B is connected with a respective barrier gate 130A, two barrier gates 130B on opposite sides of the one barrier gate 130B are free of connection with the barrier gates 130A. Similarly, if one barrier gate 130B is free of connection with the barrier gates 130A, two barrier gates 130B on opposite sides of the one barrier gate 130B are connected with the respective barrier gates 130A. As a result, the number of the barrier gates 130B is greater than the number of the barrier gates 130A.

After the barrier gates 130A and 130B are formed, the barrier gates 110A and 110B and the barrier gates 130A and 130B collectively define several cavities R1 and R2. The cavities R1 are arranged annually with respect to the center CE, and the cavities R2 are arranged annually with respect to the center CE, respectively. In greater detail, the cavities R1 are arranged along a first ring, and the cavities R2 are arranged along a second ring that surrounds the first ring. In some embodiments, the first and second rings are arranged concentrically with respect to the center CE.

As shown in the top view of FIG. 4A, each of the cavities R1 is defined by two adjacent barrier gates 130A and the barrier gate 110A. As a result, each of the cavities R1 has a circular sector top profile. That is, the top profile of each cavity R1 is defined by three sides. On the other hand, each of the cavities R2 is defined by the barrier gate 110A, the barrier gate 110B, and two adjacent barrier gates 130B. As a result, each of the cavities R2 has an annular sector top profile. That is, the top profile of each cavity R2 is defined by four sides.

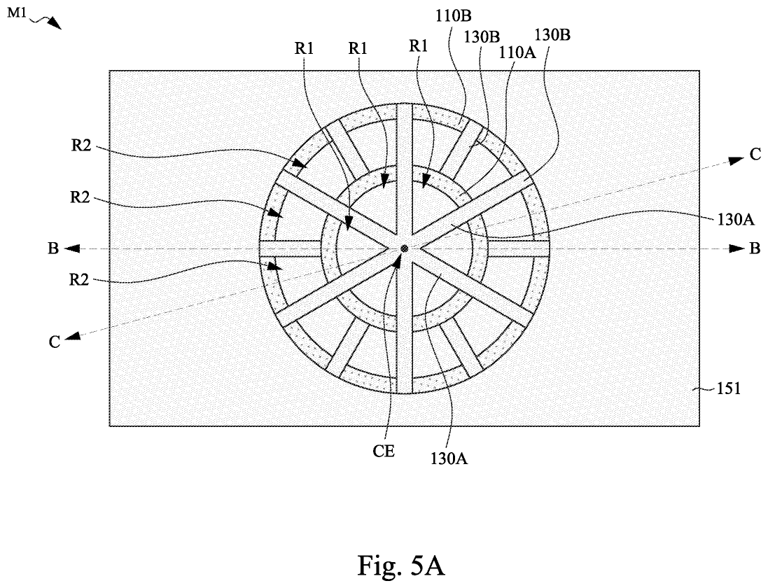

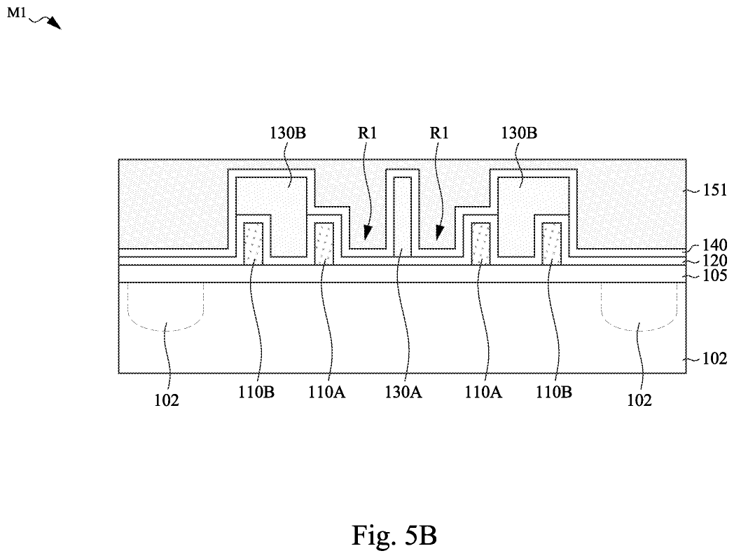

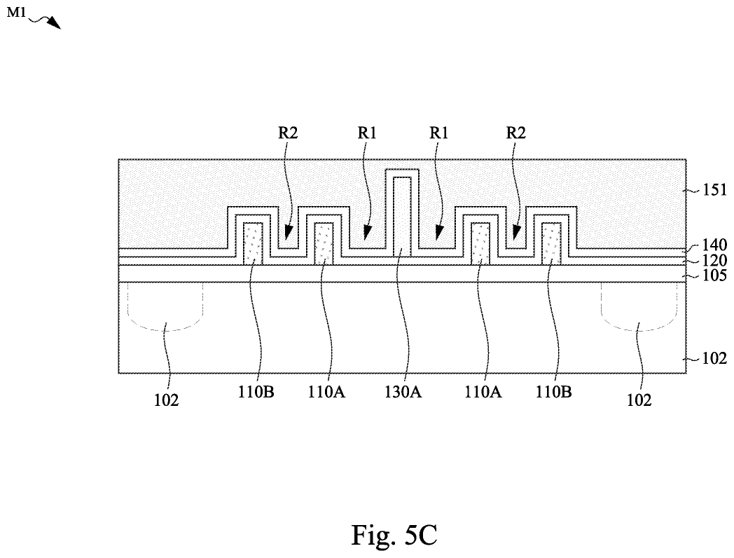

Reference is made to FIGS. 5A, 5B, and 5C. A gate dielectric layer 140 is formed over the substrate 100 and lining the underlying structure. In greater detail, the gate dielectric layer 140 is deposited in a conformal manner, such that the gate dielectric layer 140 lines the top surface of the gate dielectric layer 120, and lines the top surface and opposite sidewalls of each of the barrier gates 130A and 130B. In some embodiments, the gate dielectric layer 140 may include oxide, such as aluminum oxide (Al₂O₃), silicon oxide (SiO₂), or the like. The gate dielectric layer 120 may also include high-k dielectric material, such as HfO₂, HfSiO, HfSiON, HfTaO, HfTiO, HfZrO, zirconium oxide, aluminum oxide, titanium oxide, hafnium dioxide-alumina (HfO₂—Al₂O₃) alloy, other suitable high-k dielectric materials, and/or combinations thereof. The gate dielectric layer 140 may be formed using suitable deposition process, such as atomic layer deposition (ALD), chemical vapor deposition (CVD), physical vapor deposition (PVD), or other suitable deposition processes.

A gate layer 151 is formed over the gate dielectric layer 140. In greater detail, the gate layer 151 may cover the barrier gates 110A, 110B, 130A, and 130B, and may fill the cavities R1 and R2. In some embodiments, the gate layer 151 is deposited such that the top surface of the gate layer 151 is higher than top surfaces of the barrier gates 130A and 130B. In some embodiments, the top surfaces of the barrier gates 110A and 110B is lower than the top surface of the gate layer 151 and is higher than the bottom surfaces of the gate layer 151. Similarly, the top surfaces of the barrier gates 130A and 130B is lower than the top surface of the gate layer 151 and is higher than the bottom surfaces of the gate layer 151.

In some embodiments, the gate layer 151 may be made of conductive material, such as metal, and can also be referred to as a metal layer. In some embodiments, the gate layer 151 may include tungsten (W), aluminum (Al), copper (Cu), gold (Au), chromium (Cr), or the like. In other embodiments, the gate layer 151 may include titanium (Ti), titanium nitride (TiN), or the like. The gate layer 151 may be formed using suitable deposition process, such as sputtering, chemical vapor deposition (CVD), physical vapor deposition (PVD), atomic layer deposition (ALD), or other suitable deposition processes. In some embodiments, the gate layers 111, 131, and 151 may include a same conductive material.

Reference is made to FIGS. 6A, 6B, 6C, and 6D. The gate layer 151 is patterned to form plunger gate structures 150A and 150B separated from each other. The plunger gate structures 150A and 150B are arranged concentrically with respect to the center CE, in which the plunger gate structure 150B surrounds the plunger gate structure 150A. In some embodiments, the plunger gate structures 150A and 150B may be electrically isolated from the barrier gates 110A, 110B, 130A, and 130B through dielectric material, such as the gate dielectric layers 120 and 140 as shown in FIGS. 6B and 6C.

FIG. 6D is a schematic view of the plunger gate structure 150A, in which each of the plunger gate structure 150A include a ring structure 150A_R and a plurality of plunger gates 150A_P extends downward from the ring structure 150A_R. In greater detail, the plunger gates 150A_P may be referred to as the portions of the gate layer 151 that fill the cavities R1 as described above, and the ring structure 150A_R may be referred to as the portion of the patterned gate layer 151 above the plunger gates 150A_P. The ring structure 150A_R has an annular top profile that crosses each of the barrier gates 130A, and may be connected with the plunger gates 150A_P filled in the cavities R1. That is, the plunger gates 150A_P may be electrically connected with each other through the ring structure 150A_R.

With respect to the plunger gate structure 150B, each of the plunger gate structure 150B include a ring structure 150B_R and a plurality of plunger gates 150B_P extends downward from the ring structure 150B_R. In greater detail, the plunger gates 150B_P may be referred to as the portions of the gate layer 151 that fill the cavities R2 as described above, and the ring structure 150B_R may be referred to as the portion of the patterned gate layer 151 above the plunger gates 150B_P. The ring structure 150B_R has an annular top profile that crosses each of the barrier gates 130B, and may be connected with the plunger gates 150B_P filled in the cavities R2. That is, the plunger gates 150B_P may be electrically connected with each other through the ring structure 150B_R.

Although not shown in FIG. 6A, it is noted that the plunger gates 150A_P that fill the cavities R1 may inherit the profiles of the respective cavities R1. Accordingly, the plunger gates 150A_P may include similar top profiles as the respective cavities R1 described in FIG. 4A. Similarly, the plunger gates 150B_P that fill the cavities R2 may inherit the profiles of the respective cavities R2. Accordingly, the plunger gates 150B_P may include similar top profiles as the respective cavities R2 described in FIG. 4A. It is noted that although the cavities R1 and R2 are lined with the gate dielectric layers 120 and 140, the gate dielectric layers 120 and 140 are both deposited using conformal deposition methods, and thus the gate dielectric layers 120 and 140 would not affect the profiles of the cavities R1 and R2 defined by the barrier gates 110A and 110B and the barrier gates 130A and 130B. Detailed description related to the profiles of the cavities R1 and R2 have been discuss above, and will not be repeated for brevity.

Referring to FIG. 6A, it can be seen that the barrier gates 110A and 110B, the ring structure 150A_R of the plunger gate structure 150A, and the ring structure 150B_R of the plunger gate structure 150B include annular top profiles (or circular-ring shape top profiles), and are arranged concentrically with respect to the center CE. Moreover, the barrier gate 110B surrounds the ring structure 150B_R of the plunger gate structure 150B, the ring structure 150B_R of the plunger gate structure 150B surrounds the barrier gate 110A, and the barrier gate 110A surrounds the ring structure 150A_R of the plunger gate structure 150A.

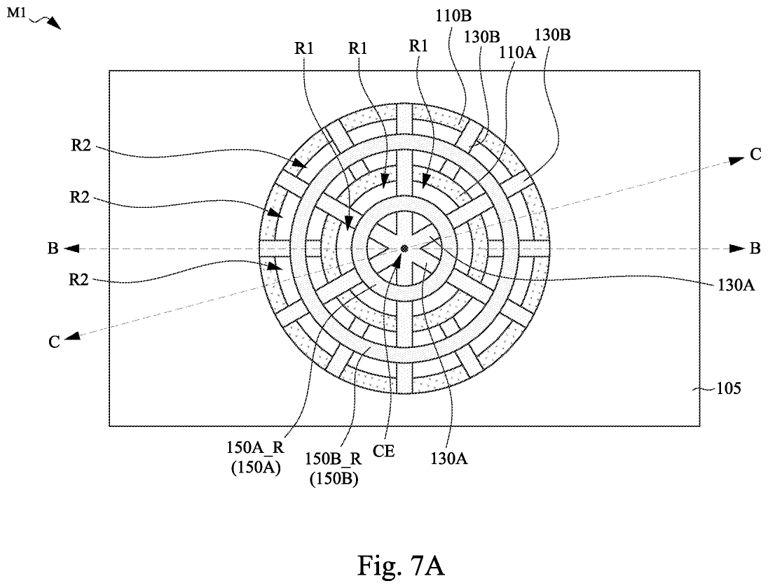

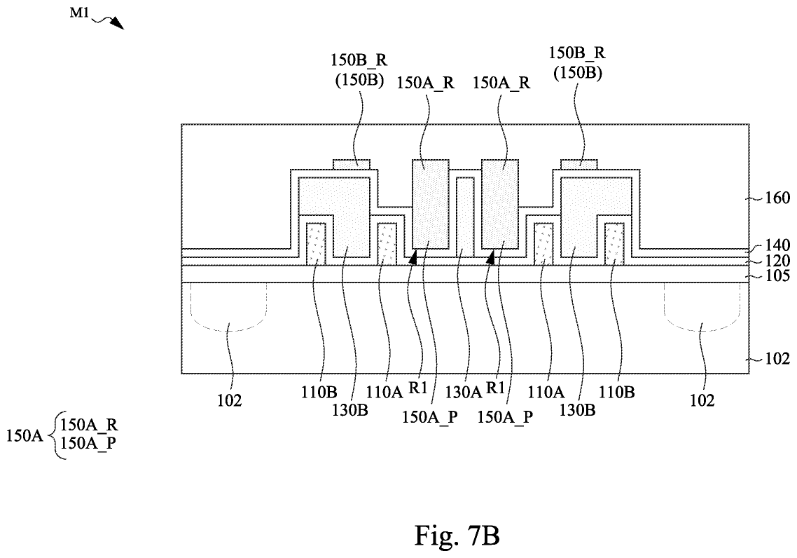

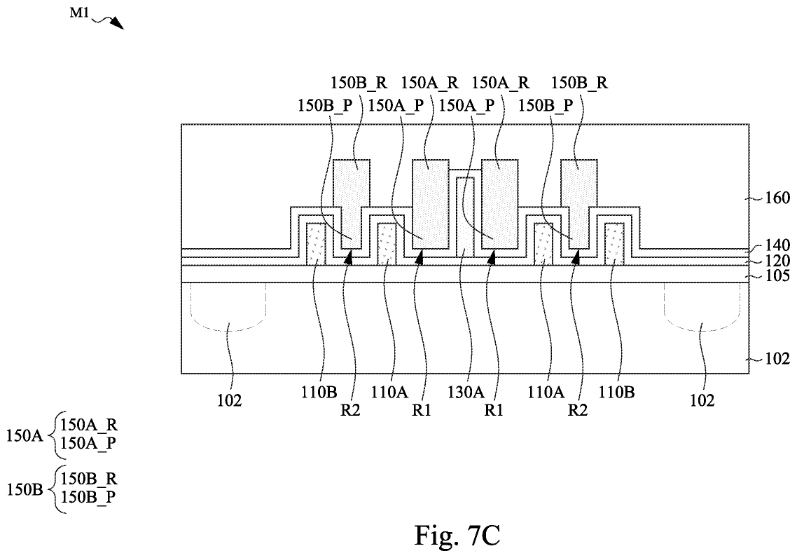

Reference is made to FIGS. 7A, 7B, and 7C. A passivation layer 160 is formed over the substrate 100 and covering the plunger gate structures 150A and 150B. In some embodiments, the passivation layer 160 may include silicon oxide, silicon nitride, silicon oxynitride, tetraethoxysilane (TEOS), phosphosilicate glass (PSG), borophosphosilicate glass (BPSG), low-k dielectric material, and/or other suitable dielectric materials. Examples of low-k dielectric materials include, but are not limited to, fluorinated silica glass (FSG), carbon doped silicon oxide, amorphous fluorinated carbon, parylene, bis-benzocyclobutenes (BCB), or polyimide. The passivation layer 160 may be formed using, for example, CVD, ALD, spin-on-glass (SOG) or other suitable techniques. In some embodiments, the passivation layer 160 may include different dielectric material than the gate dielectric layers 105, 120, and 140. For example, the passivation layer 160 may include silicon oxide (SiO₂), and the gate dielectric layers 105, 120, and 140 may include aluminum oxide (Al₂O₃).

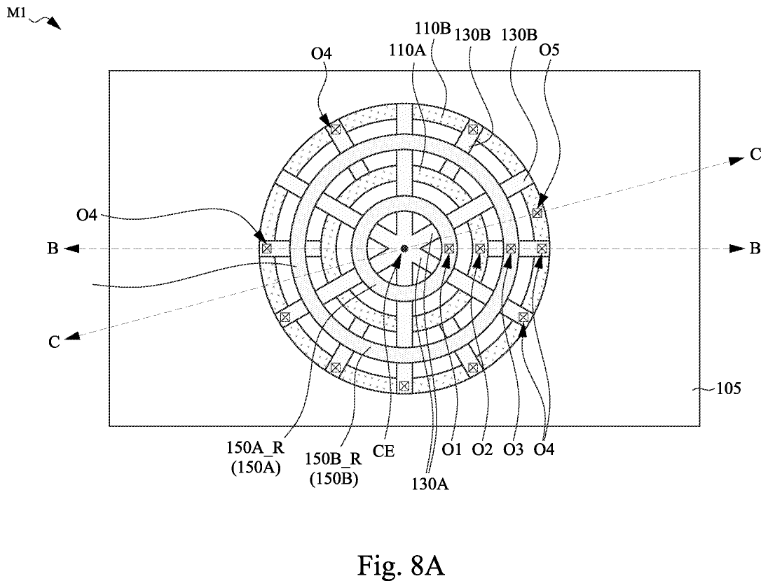

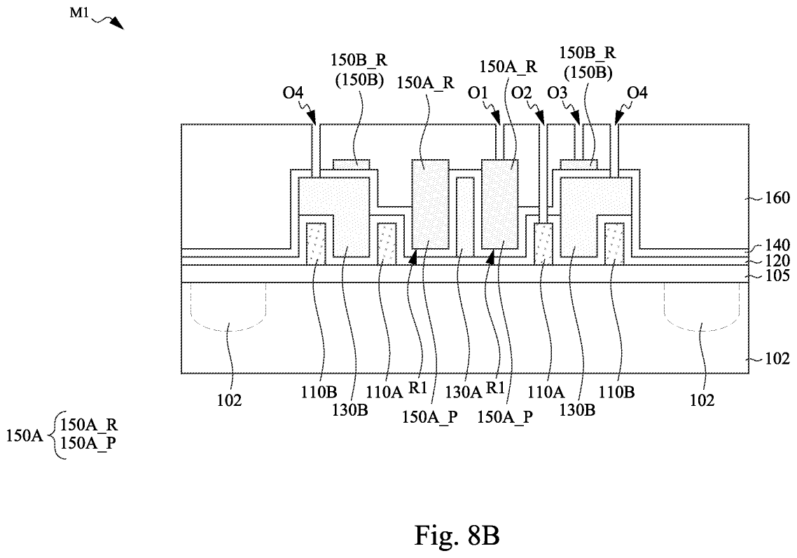

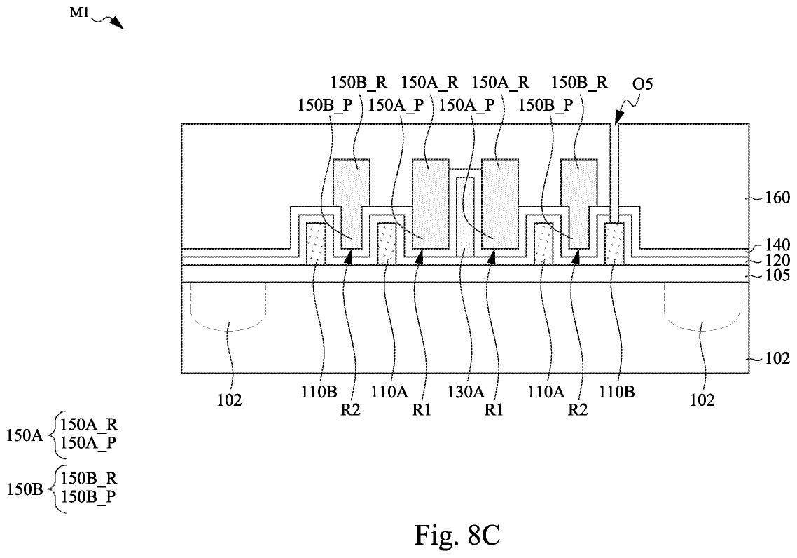

Reference is made to FIGS. 8A, 8B, and 8C. The passivation layer 160 is patterned to form via openings O1, O2, O3, O4, and O5 in the passivation layer 160. In some embodiments, the via opening O1 extends through the passivation layer 160 and exposes the top surface of the plunger gate structure 150A. The via opening O2 extends through the passivation layer 160, the gate dielectric layer 140, and the gate dielectric layer 120, and exposes the top surface of the barrier gate 110A. The via opening O3 extends through the passivation layer 160 and exposes the top surface of the plunger gate structure 150B. The via openings O4 extend through the passivation layer 160 and the gate dielectric layer 140, and expose the top surfaces of the respective barrier gates 130B. The via opening O5 extends through the passivation layer 160 and the gate dielectric layers 120 and 140, and exposes the top surface of the barrier gate 110B (see FIG. 8C).

The via openings O1, O2, O3, O4, and O5 may be formed by, for example, forming a patterned mask (e.g., photoresist) layer over the passivation layer 160, the patterned mask may include openings that define the positions of the via openings O1, O2, O3, O4, and O5, performing an etching process to remove portions of the passivation layer 160 and the gate dielectric layers 120 and 140 exposed through the openings of the patterned mask, and then removing the patterned mask once the etching process is complete. In some embodiments, the etching process may be reactive ion etching (RIE) process, or may be other suitable etching process.

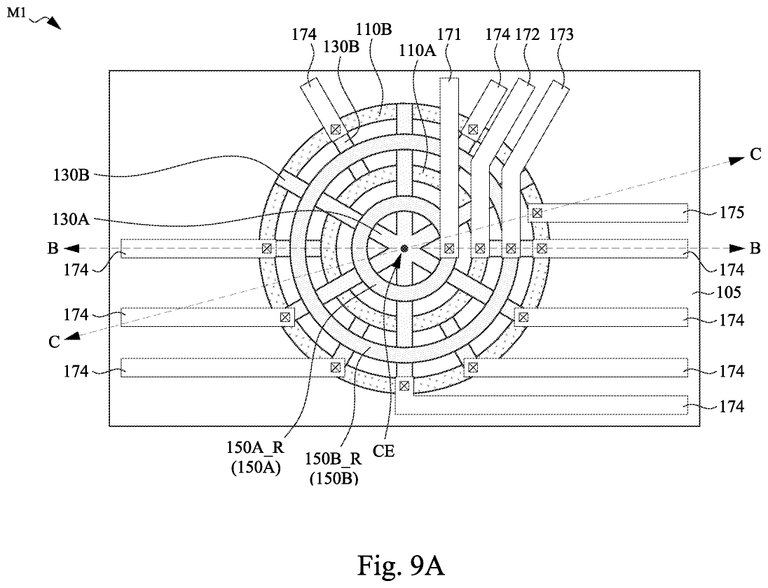

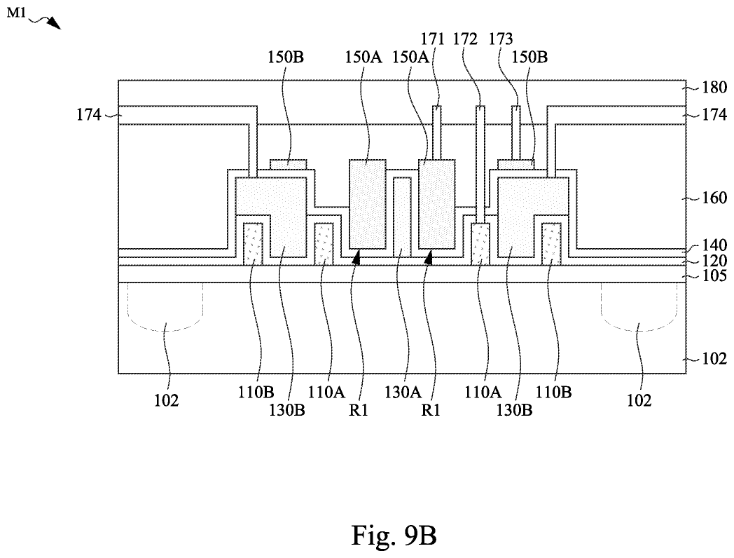

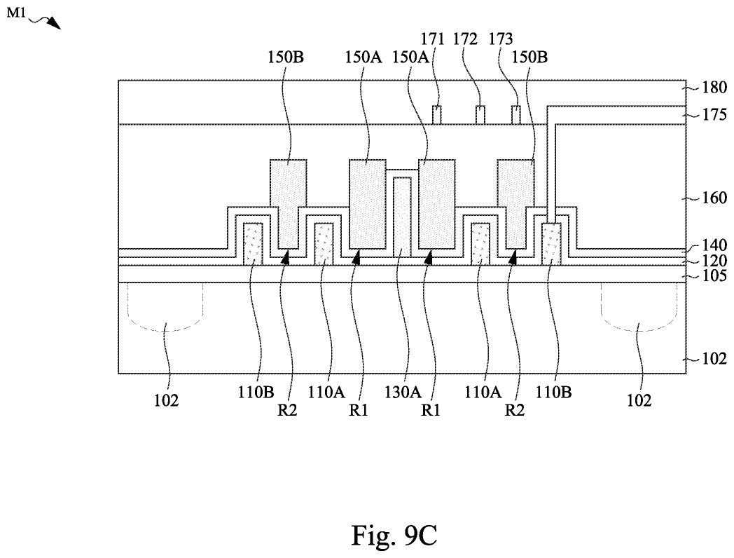

Reference is made to FIGS. 9A, 9B, and 9C. Contacts 171, 172, 173, 174, and 175 are formed over the passivation layer 160 and fill the respective via openings O1, O2, O3, O4, and O5. In greater detail, the contact 171 has a metal line portion over the passivation layer 160 and a via portion filling the opening O1, such that the contact 171 is electrically connected to the plunger gate structure 150A. The contact 172 has a metal line portion over the passivation layer 160 and a via portion filling the opening O2, such that the contact 172 is electrically connected to the barrier gate 110A. The contact 173 has a metal line portion over the passivation layer 160 and a via portion filling the opening O3, such that the contact 173 is electrically connected to the plunger gate structure 150B. The contacts 174 each has a metal line portion over the passivation layer 160 and a via portion filling the respective opening O4, such that the contacts 174 are electrically connected to the respective barrier gates 130B. The contact 175 has a metal line portion over the passivation layer 160 and a via portion filling the opening O5, such that the contact 175 is electrically connected to the barrier gate 110B. In some embodiments, because some of the barrier gates 130A are connected with the barrier gates 130B, the barrier gates 130A may also be electrically connected to the contacts 174 through the respective barrier gates 130B.

The contacts 171, 172, 173, 174, and 175 may be formed by, for example, forming a patterned mask (e.g., photoresist) layer over the passivation layer 160, the patterned mask may include openings that define the positions and profiles of the contacts 171, 172, 173, 174, and 175, depositing a conductive material over the substrate 100 and filling the openings of the patterned mask and the via openings O1, O2, O3, O4, and O5 in the passivation layer 160, and then performing a lift-off process to remove the patterned mask, leaving the portions of the conductive material within the openings of the patterned mask and the via openings O1, O2, O3, O4, and O5 remaining over the substrate 100 as the contacts 171, 172, 173, 174, and 175.

In some embodiments, the contacts 171, 172, 173, 174, and 175 may include gold (Au), chromium (Cr), copper (Cu), or the like. The contacts 171, 172, 173, 174, and 175 may be formed using suitable deposition process, such as sputtering, chemical vapor deposition (CVD), physical vapor deposition (PVD), atomic layer deposition (ALD), or other suitable deposition processes.

After the contacts 171 to 175 are formed, a passivation layer 180 is formed over the passivation layer 160 and covering the contacts 171 to 175. The passivation layer 180 may include similar material as the passivation layer 160, and thus relevant details will not be repeated for brevity.

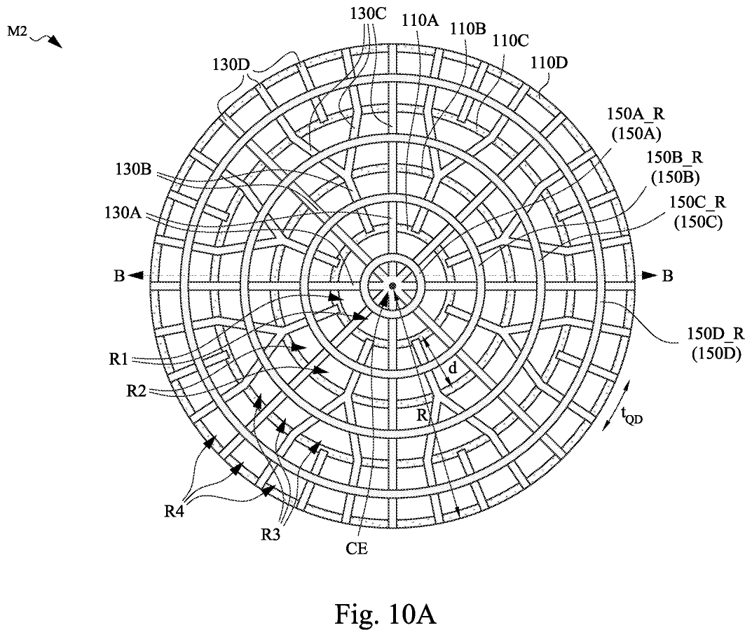

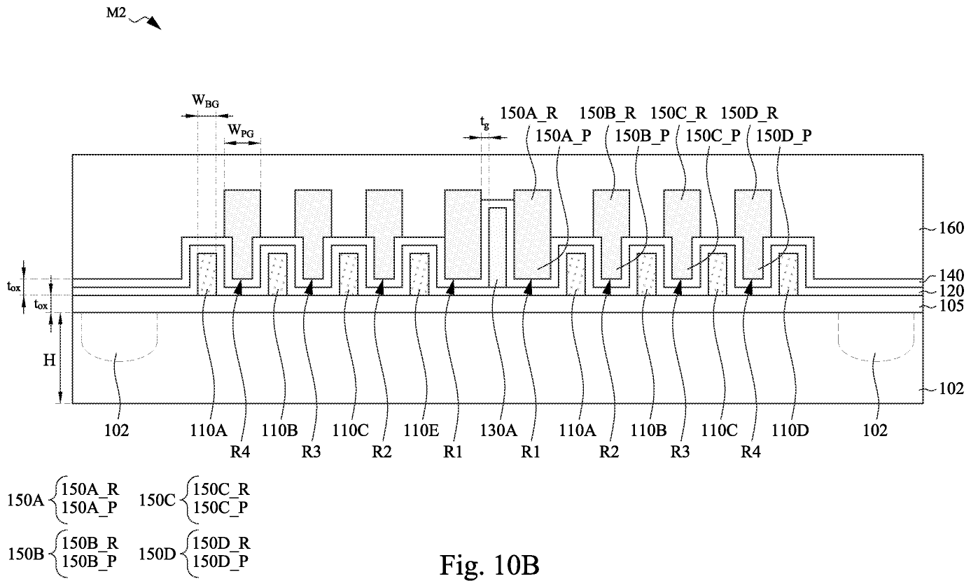

FIG. 10A is a top view of a memory device in accordance with some embodiments of the present disclosure. FIG. 10B is a cross-sectional view of a memory device in accordance with some embodiments of the present disclosure. In greater detail, FIG. 10B is a cross-sectional view along line B-B of FIG. 10A. It is noted that some elements of FIGS. 10A and 10B are similar with those described with respect to FIGS. 1A to 9C, such elements are labeled the same and relevant details will not be repeated for brevity.

The Embodiment of FIGS. 10A and 10B is different from the embodiment described with respect to FIGS. 1A to 9C, in that the memory device of FIGS. 10A and 10B further includes barrier gates 110C and 110D, barrier gates 130C and 130D, and plunger gate structures 150C and 150D.

With respect to the barrier gates 110C and 110D, the barrier gates 110C and 110D each includes an annular top profile (or circular-ring shape), which is similar to the barrier gates 110A and 110B as described above. In some embodiments, the barrier gates 110A, 110B, 110C, and 110D are arranged concentrically with respect to the center CE, in which the barrier gate 110D surrounds the barrier gate 110C, the barrier gate 110C surrounds the barrier gate 110B, and the barrier gate 110B surrounds the barrier gate 110A. In some embodiments, the barrier gates 110A to 110D may also be referred to as annular barrier gates.

The barrier gates 110C and 110D may be formed together with the barrier gates 110A and 110B during the process of patterning the gate layer 111 as described in FIGS. 2A and 2B. After the barrier gates 110A to 110D are formed, the gate dielectric layer 120 is formed over the substrate 100 and lining the exposed surfaces of the barrier gates 110A to 110D as similar to those described in FIGS. 3A and 3B.

With respect to the barrier gates 130C and 130D, the barrier gates 130C extend from the barrier gate 110B to the barrier gate 110C, and the barrier gates 130D extend from the barrier gate 110C to the barrier gate 110D. As shown in the top view of FIG. 10A, each of the barrier gates 130C and 130D includes a linear top profile (or bar-shape). In some embodiments, each of the barrier gates 130D and some of the barrier gates 130C are arranged radially with respect to the center CE.

The barrier gates 130C and 130D may be formed together with the barrier gates 130A and 130B during the process of patterning the gate layer 131 as described in FIGS. 4A, 4B, and 4C. After the barrier gates 130A to 130D are formed, the gate dielectric layer 140 is formed over the substrate 100 and lining the exposed surfaces of the barrier gates 130A to 130D as similar to those described in FIGS. 5A, 5B, and 5C.

After the barrier gates 130A to 130D are formed, several cavities R1, R2, R3 and R4 are formed. In greater detail, the barrier gates 110B/110C/110D and the barrier gates 130C/130D collectively define the cavities R3 and R4. The cavities R3 are arranged annually with respect to the center CE, and the cavities R4 are arranged annually with respect to the center CE, respectively. In greater detail, the cavities R3 are arranged along a third ring, and the cavities R4 are arranged along a fourth ring that surrounds the third ring.

As shown in the top view of FIG. 10A, the barrier gates 130C are connected with the respective barrier gates 130B. However, one barrier gate 130B may be connected with a single barrier gate 130C, while another one barrier gate 130B may also be connected with two barrier gates 130C. This will result in that the cavities R3 have different top profiles. For example, first portions of the cavities R3 are defined by two adjacent barrier gates 130C and the barrier gate 110C. The top profile of the first portions of the cavities R3 is defined by three sides, and has a circular sector top profile. On the other hand, second portions of the cavities R3 are defined by two adjacent barrier gates 130C, the barrier gate 110B, and the barrier gate 110C. The top profile of the second portions of the cavities R3 is defined by four sides, and has an annular sector top profile.

Each of the cavities R4 is defined by the barrier gate 110C, the barrier gate 110D, and two adjacent barrier gates 130D. As a result, each of the cavities R2 has an annular sector top profile. That is, the top profile of each cavity R4 is defined by four sides. In some embodiments, parts of the barrier gates 130D are connected with the barrier gates 130C, while parts of the barrier gates 130D are free of connection with the barrier gates 130C.

The plunger gate structures 150A, 150B, 150C, and 150D are arranged concentrically with respect to the center CE, in which the plunger gate structure 150D surrounds the plunger gate structure 150C, the plunger gate structure 150C surrounds the plunger gate structure 150B, and the plunger gate structure 150B surrounds the plunger gate structure 150A.

The plunger gate structures 150C and 150D may be formed together with the plunger gate structures 150A and 150B during the process of patterning the gate layer 151 as described in FIGS. 6A, 6B, and 6C. After the plunger gate structures 150A to 150D are formed, the passivation layer 160 is formed over the substrate 100 and lining the exposed surfaces of the plunger gate structures 150A to 150D as similar to those described in FIGS. 7A, 7B, and 7C.

With respect to the plunger gate structure 150C, each of the plunger gate structure 150C include a ring structure 150C_R and a plurality of plunger gates 150C_P extends downward from the ring structure 150C_R. In greater detail, the plunger gates 150C_P may be referred to as the portions of the gate layer 151 that fill the cavities R3, and the ring structure 150C_R may be referred to as the portion of the patterned gate layer 151 above the plunger gates 150C_P. The ring structure 150C_R has an annular top profile that crosses each of the barrier gates 130C, and may be connected with the plunger gates 150C_P filled in the cavities R3. That is, the plunger gates 150C_P may be electrically connected with each other through the ring structure 150C_R.

With respect to the plunger gate structure 150D, each of the plunger gate structure 150D include a ring structure 150D_R and a plurality of plunger gates 150D_P extends downward from the ring structure 150D_R. In greater detail, the plunger gates 150D_P may be referred to as the portions of the gate layer 151 that fill the cavities R4, and the ring structure 150D_R may be referred to as the portion of the patterned gate layer 151 above the plunger gates 150D_P. The ring structure 150D_R has an annular top profile that crosses each of the barrier gates 130D, and may be connected with the plunger gates 150D_P filled in the cavities R4. That is, the plunger gates 150D_P may be electrically connected with each other through the ring structure 150D_R.

Although not shown in FIG. 10A, it is noted that the plunger gates 150C_P that fill the cavities R3 may inherit the profiles of the respective cavities R3. Accordingly, the plunger gates 150C_P may include similar top profiles as the respective cavities R3. Similarly, the plunger gates 150D_P that fill the cavities R4 may inherit the profiles of the respective cavities R4. Accordingly, the plunger gates 150D_P may include similar top profiles as the respective cavities R4. It is noted that although the cavities R1 to R4 are lined with the gate dielectric layers 120 and 140, the gate dielectric layers 120 and 140 are both deposited using conformal deposition methods, and thus the gate dielectric layers 120 and 140 would not affect the profiles of the cavities R1 to R4 defined by the barrier gates 110A to 110D and the barrier gates 130A to 130D.

In operation of the memory device M2, the plunger gates 150A_P to 150D_P may define qubits (or quantum dot; QD) in the substrate 100. Stated another way, the locations of the qubits are defined by the barrier gates 110A to 110D and the barrier gates 130A to 130D. The locations of the qubits correspond to the respective plunger gates 150A_P to 150D_P, and thus the plunger gates 150A_P to 150D_P may also be referred to as the qubits of the memory device M2. The qubits of the memory device M2 are arranged in a circular array on a center region of the substrate 100, and the source/drain regions 102 are within a peripheral region of the substrate 100 that surrounds the center region of the substrate 100. In some embodiments, the plunger gates 150A_P to 150D_P may also be referred to as the memory cells of the memory device M2.

With respect to the cross-sectional view of FIG. 10B. In some embodiments, the thickness H of the substrate 100 is in a range from about 500 μm to about 2000 μm.

In some embodiments, the thickness tox of the gate dielectric layers 105, 120, and 140 is in a range from about 5 nm to about 20 nm. In some embodiments, the height HG of the barrier gates 130A to 130D, and the plunger gates 150A_P to 150D_P is in a range from about 25 nm to about 50 nm. In some embodiments, the width W_{BG} of the barrier gates 110A to 110D and the width W_{PG} of the plunger gates 150A_P to 150D_P are in a range from about 20 nm to about 50 nm. In some embodiments, the thickness t_{g} of the dielectric layer (e.g., dielectric layer 140) between the overlapping gates (e.g., the barrier gate 130A and the plunger gates 150A) is in a range from about 5 nm to about 20 nm. In some embodiments, the critical gate spacing t_{crit} between two plunger gates (e.g., plunger gates 150A_P and 150B_P) may be greater than W_{PG}+2tₒₓ. In some embodiments, the critical gate spacing t_{crit} between two barrier gates (e.g., barrier gates 110A and 110B) may be greater than W_{BG}+2tₒₓ.

With respect to the top view of FIG. 10A, the number of the plunger gates 150A_P at the 1^{st} ring may be λ (e.g., 8 in this case). The number of the plunger gates 150B_P at the 2^{nd} ring may be λ*2 (e.g., 16 in this case). The number of the plunger gates 150C_P at the 3^{rd} ring may be λ*3 (e.g., 24 in this case). The number of the plunger gates 150D_P at the 4^{th} ring may be λ*4 (e.g., 32 in this case). That is, the number of the plunger gates at n^{th} ring would be λ*n, in which λ is the number of plunger gates at the 1^{st} ring, and n is positive integer.

In FIG. 10A, it can be seen that each plunger gates may include a thickness t_{QD} along circumferential direction. For the 1^{st} ring, the thickness top of each plunger gate (e.g., plunger gate 150A_P) is 2πd/λ, in which d is the spacing between adjacent two annular barrier gates (e.g., barrier gates 110A to 110D). For the n^{th} ring, the thickness t_{QD} of each plunger gate is 2πR/nλ, in which R=n×d (radius of the n^{th} ring). That is, the thickness t_{QD} of each plunger gate is

$$\frac{2 π ( n \times d )}{n λ} = \frac{2 π d}{λ} .$$

In some embodiments, the thickness t_{QD} may be large enough, such as greater than the critical gate spacing t_{crit} (e.g., t_{QD}≥t_{crit}). That is,

$$\frac{2 π d}{λ} \geq {t}_{crit} ,$$

and thus

$$d \geq \frac{{t}_{crit} λ}{2 π} .$$

In some embodiments, if λ≥6, the value

$$d = \frac{{t}_{crit} λ}{2 π}$$

can be chosen to ensure that d is not too small to be fabricated. However, if λ<6, the value of d must be selected as t_{crit}. As a result, the density in 2D circular QD array can be optimized by choosing λ is equal to or greater than 6. In some embodiments, λ is in a range from 6 to 12.

The density of the qubits (e.g., plunger gates) can be expressed as:

$$\begin{matrix}\frac{( {T}_{1} + {T}_{2} + ⋯ + {T}_{n} )}{{π ( R )}^{2}} = \frac{( λ + 2 λ + ⋯ + n λ )}{{π ( R )}^{2}} \\ = \frac{λ ( 1 + 2 + ⋯ + n )}{{π ( R )}^{2}} \\ = \frac{\frac{λ n ( 1 + n )}{2}}{{π ( n \times d )}^{2}}\end{matrix}$$

In some embodiments, when n is a large number, the density of the qubits (e.g., plunger gates) can be expressed as:

$$\begin{matrix}= \frac{\frac{λ n ( 1 + n )}{2}}{{π ( n \times d )}^{2}} \\ \approx \frac{\frac{λ n ( n )}{2}}{{π ( n \times d )}^{2}} \\ = \frac{λ {n}^{2}}{2 {π ( n \times d )}^{2}}\end{matrix}$$

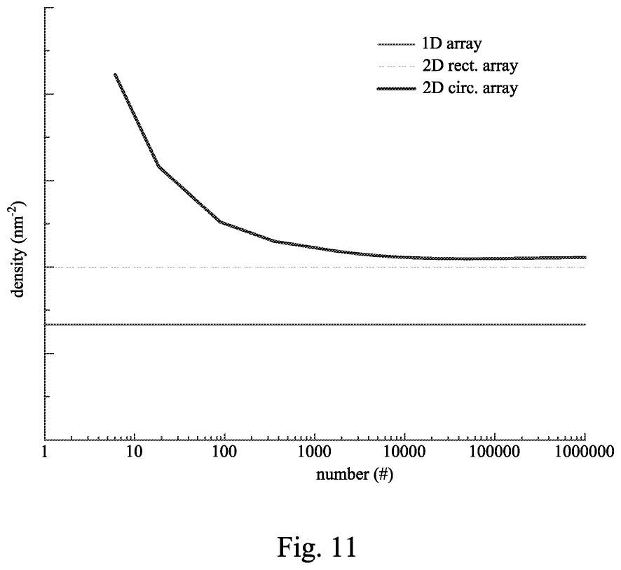

FIG. 11 shows simulation results in accordance with some embodiments of the present disclosure. In greater detail, simulation results of three different arrangements of qubits are shown. It can be seen that when the qubits are arranged in a 2-D circular array as provided by the present disclosure, the density of qubits may be higher than qubits arranged in a 1-D linear array or in a 2-D rectangular array. Accordingly, circular gate design enables higher quantum dot density and a more compact device configuration. The design of 2-D qubit array allows for programmable entanglement between quantum dots.

According to the aforementioned embodiments, it can be seen that the present disclosure offers advantages in fabricating integrated circuits. It is understood, however, that other embodiments may offer additional advantages, and not all advantages are necessarily disclosed herein, and that no particular advantage is required for all embodiments. Embodiments of the present disclosure provide a qubit memory device, in which the qubits are arranged in a 2-D circular array. The circular gate design enables higher quantum dot density and a more compact device configuration.

In some embodiments of the present disclosure, a memory device includes a substrate. First plunger gates are over the substrate and arranged annularly. Second plunger gates are arranged annularly around the first plunger gates. A first annular barrier gate is over the substrate and disposed between the first plunger gates and the second plunger gates.

In some embodiments, the memory device further includes first linear barrier gates over the substrate, wherein each of the first linear barrier gates separates correspond two of the first plunger gates.

In some embodiments, the first linear barrier gates extend radially from a top view.

In some embodiments, the memory device further includes a second annular barrier gate over the substrate and surrounding the first annular barrier gate. Second linear barrier gates extend from the first annular barrier gate to the second annular barrier gate, wherein each of the second linear barrier gates separates correspond two of the second plunger gates.

In some embodiments, one of the second linear barrier gates is connected with one of the first linear gates.

In some embodiments, the memory device further includes a first ring structure above the first plunger gates and electrically connecting the first plunger gates with each other.

In some embodiments, a number of the second plunger gates is greater than a number of the first plunger gates.

In some embodiments, the number of the second plunger gates is multiple times the number of the first plunger gates.

In some embodiments of the present disclosure, a memory device includes a substrate. A gate dielectric layer is over the substrate. A first plunger gate structure and a second plunger gate structure are over the gate dielectric layer, wherein in a top view the first and second plunger gate structures are arranged concentrically, and wherein each of the first and second plunger gate structures comprises a ring structure and plunger gates extend downwardly from the ring structure. Barrier gates are over the gate dielectric layer, wherein in a cross-sectional view each of the plunger gates of the first and second plunger gate structures is laterally between adjacent two of the barrier gates.

In some embodiments, the plunger gates of the first plunger gate structure are arranged annularly, and the plunger gates of the second plunger gate structure are arranged annularly.

In some embodiments, the barrier gates comprise an annular barrier gate, and the annular barrier gate separates the first plunger gate structure from the second plunger gate structure.

In some embodiments, the barrier gates comprise linear barrier gates, and each of the linear barrier gates is between two of the plunger gates.

In some embodiments, top surfaces of the linear barrier gates are higher than a top surface of the annular barrier gate in the cross-sectional view.

In some embodiments, top surfaces of the first and second plunger gate structures are higher than top surfaces of the barrier gates in the cross-sectional view.

In some embodiments, the first and second plunger gate structures and the barrier gates are made of conductive materials.

In some embodiments of the present disclosure, a method includes forming source/drain regions in a substrate; forming a first gate dielectric layer over the substrate; forming barrier gates over the substrate, the barrier gates defining a first set of cavities and a second set of cavities arranged around the first set of cavities, wherein cavities in the first set of cavities are arranged annularly, and cavities in the second set of cavities are arranged annularly; and forming plunger gates in the cavities.

In some embodiments, forming the barrier gates comprises forming annular barrier gates of the barrier gates over the substrate; and forming linear barrier gates of the barrier gates over the substrate after forming the annular barrier gates of the barrier gates.

In some embodiments, the method further includes forming a second gate dielectric layer lining the annular barrier gates of the barrier gates prior to forming the linear barrier gates of the barrier gates; and forming a third gate dielectric layer lining the linear barrier gates of the barrier gates prior to forming the plunger gates.

In some embodiments, forming the plunger gates further comprises forming ring structures above and connected with the plunger gates.

In some embodiments, the barrier gates and the plunger gates are made of conductive materials.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A memory device, comprising:
a substrate;
first plunger gates over the substrate and arranged annularly;
second plunger gates arranged annularly around the first plunger gates; and
a first annular barrier gate over the substrate and disposed between the first plunger gates and the second plunger gates.

2. The memory device of claim 1, further comprising:
first linear barrier gates over the substrate, wherein each of the first linear barrier gates separates correspond two of the first plunger gates.

3. The memory device of claim 2, wherein the first linear barrier gates extend radially from a top view.

4. The memory device of claim 2, further comprising:
a second annular barrier gate over the substrate and surrounding the first annular barrier gate; and
second linear barrier gates extending from the first annular barrier gate to the second annular barrier gate, wherein each of the second linear barrier gates separates correspond two of the second plunger gates.

5. The memory device of claim 4, wherein one of the second linear barrier gates is connected with one of the first linear barrier gates.

6. The memory device of claim 1, further comprising a first ring structure above the first plunger gates and electrically connecting the first plunger gates with each other.

7. The memory device of claim 1, wherein a number of the second plunger gates is greater than a number of the first plunger gates.

8. The memory device of claim 7, wherein the number of the second plunger gates is multiple times the number of the first plunger gates.

9. A memory device, comprising:
a substrate;
a gate dielectric layer over the substrate;
a first plunger gate structure and a second plunger gate structure over the gate dielectric layer, wherein in a top view the first and second plunger gate structures are arranged concentrically, and wherein each of the first and second plunger gate structures comprises a ring structure and plunger gates extend downwardly from the ring structure; and
barrier gates over the gate dielectric layer, wherein in a cross-sectional view each of the plunger gates of the first and second plunger gate structures is laterally between adjacent two of the barrier gates.

10. The memory device of claim 9, wherein the plunger gates of the first plunger gate structure are arranged annularly, and the plunger gates of the second plunger gate structure are arranged annularly.

11. The memory device of claim 9, wherein the barrier gates comprise an annular barrier gate, and the annular barrier gate separates the first plunger gate structure from the second plunger gate structure.

12. The memory device of claim 11, wherein the barrier gates comprise linear barrier gates, and each of the linear barrier gates is between two of the plunger gates.

13. The memory device of claim 12, wherein top surfaces of the linear barrier gates are higher than a top surface of the annular barrier gate in the cross-sectional view.

14. The memory device of claim 9, wherein top surfaces of the first and second plunger gate structures are higher than top surfaces of the barrier gates in the cross-sectional view.

15. The memory device of claim 9, wherein the first and second plunger gate structures and the barrier gates are made of conductive materials.

16. A method, comprising:
forming source/drain regions in a substrate;
forming a first gate dielectric layer over the substrate;
forming barrier gates over the substrate, the barrier gates defining a first set of cavities and a second set of cavities arranged around the first set of cavities, wherein cavities in the first set of cavities are arranged annularly, and cavities in the second set of cavities are arranged annularly; and
forming plunger gates in the cavities.

17. The method of claim 16, wherein forming the barrier gates comprises:
forming annular barrier gates of the barrier gates over the substrate; and
forming linear barrier gates of the barrier gates over the substrate after forming the annular barrier gates of the barrier gates.

18. The method of claim 17, further comprising:
forming a second gate dielectric layer lining the annular barrier gates of the barrier gates prior to forming the linear barrier gates of the barrier gates; and
forming a third gate dielectric layer lining the linear barrier gates of the barrier gates prior to forming the plunger gates.

19. The method of claim 16, wherein forming the plunger gates further comprises forming ring structures above and connected with the plunger gates.

20. The method of claim 16, wherein the barrier gates and the plunger gates are made of conductive materials.
